(19) United States
(12) Patent Application Publication
(10) Pub. No.: US 2003/0134504 A1
(43) Pub. Date: Jul. 17, 2003

(54) Method of making an inlaid structure in a semiconductor device

(76) Inventors: Dean J. Denning, Del Valle, TX (US); Md Rabiul Islam, Austin, TX (US); Sam S. Garcia, Austin, TX (US)

Correspondence Address: MOTOROLA INC, AUSTIN INTELLECTUAL PROPERTY, LAW SECTION, 7700 WEST PARMER LANE MD: TX32/PL02, AUSTIN, TX, 78729

(21) Appl. No.: 10/047,675

(22) Filed: Jan. 14, 2002

(51) Int. Cl. H01L 21/4763; H01L 21/44

(52) U.S. Cl. 438/637; 438/687; 438/678; 438/675; 438/643

(57) ABSTRACT

In making inlaid structures in a semiconductor device, such as vias and trenches, a cavity is formed to expose an underlying metal layer. A degas step is then performed on the device which heats the device. If the device is then subjected to an RF sputter clean, some of the exposed metal is splattered onto the sidewall of the cavity. The problem that was discovered is that if the sidewall is too hot, this metal agglomerates. These agglomerations on the sidewall operate to block the continuous deposition of a seed layer. If the seed layer is not continuous, some portions of the seed layer may not receive the voltage necessary for the subsequent deposition by electroplating, leaving voids. To avoid these agglomerations, the device is actively cooled after the degas and before the sputtering commences so that agglomerations are not formed on the sidewall during the sputter clean.

### FIELD OF THE INVENTION

The present invention relates generally to semiconductor devices and more specifically to the formation of inlaid structures in a semiconductor device.

### RELATED ART

The formation of inlaid structures within a semiconductor device include the formation of cavities which expose an underlying metal layer, such as vias and trenches. The trenches may exist at different levels within a semiconductor device (i.e. may form different metal layers) and the vias generally provide contacts between trenches of different metal layers. FIG. 1 illustrates the formation of a semiconductor device 10 having a substrate layer 12. Substrate layer 12 may include, for example, silicon, silicon germanium, etc. Alternatively, substrate layer 12 may be an SOI (Silicon-on-Insulator) substrate. Semiconductor device 10 includes an active device layer 13 which may include any number of transistors to implement different functions. For example, active device layer 13 may include a variety of different layers and sections used to form various different types of circuits. Semiconductor device 10 also includes a dielectric layer 15 overlying active device layer 13, and a first metal layer 14 overlying dielectric layer 15. First metal layer 14 is generally patterned to provide interconnects for the devices within active device layer 13. Dielectric layer 15 may include BPSG (Boron Phospho Silicate Glass), BPTEOS (Boron Phospho Tetraethylorthosilicate), or any other appropriate dielectric, and first metal layer 14 generally includes copper.

Semiconductor device 10 also includes a second dielectric layer 16 overlying first metal layer 14 and an intermetal isolation layer 20 overlying the second dielectric layer. Second dielectric layer 16 and intermetal isolation layer 20 have a via hole 24 formed therein. Second dielectric layer 16 may include PEN (Plasma Enhanced Nitride), SiON (Silicon Oxynitride), or any other appropriate material. Intermetal isolation layer 20 may include TEOS, FTEOS (Fluorinated TEOS), any appropriate low-K dielectric (those having a dielectric constant of below approximately 3.5), or any other appropriate material. (Note that intermetal isolation layer 20 may also be referred to as dielectric layer 20 or intermetal dielectric layer 20.) (Note that semiconductor device 10 may include any number of patterned metal layers similar to first metal layer 14, where the metal layers are interconnected via any number of vias.) Conventional processing steps may be used to form semiconductor device 10 up to the formation of via hole 24 of FIG. 1. At some later point in processing, via hole 24 is filled to provide an electrical contact to first metal layer 14; therefore, a need exists for a via fill process that results in an electrical contact having low resistance.

### BRIEF DESCRIPTION OF THE DRAWINGS

The present invention is illustrated by way of example and not limited by the accompanying figures, in which like references indicate similar elements, and in which:

FIG. 1 illustrates a via hole in accordance with the prior art;

FIGS. 2-4 illustrate sequential cross sectional views of an inlaid structure illustrating a previously unknown problem;

FIGS. 5-7 illustrate sequential cross sectional views of an inlaid structure in accordance with one embodiment of the present invention;

FIG. 8 illustrates a process flow in accordance with one embodiment of the present invention; and

FIG. 9 illustrates a metal deposition tool in accordance with one embodiment of the present invention.

FIG. 10 illustrates a cooling chuck that may be used in the metal deposition tool of FIG. 9.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

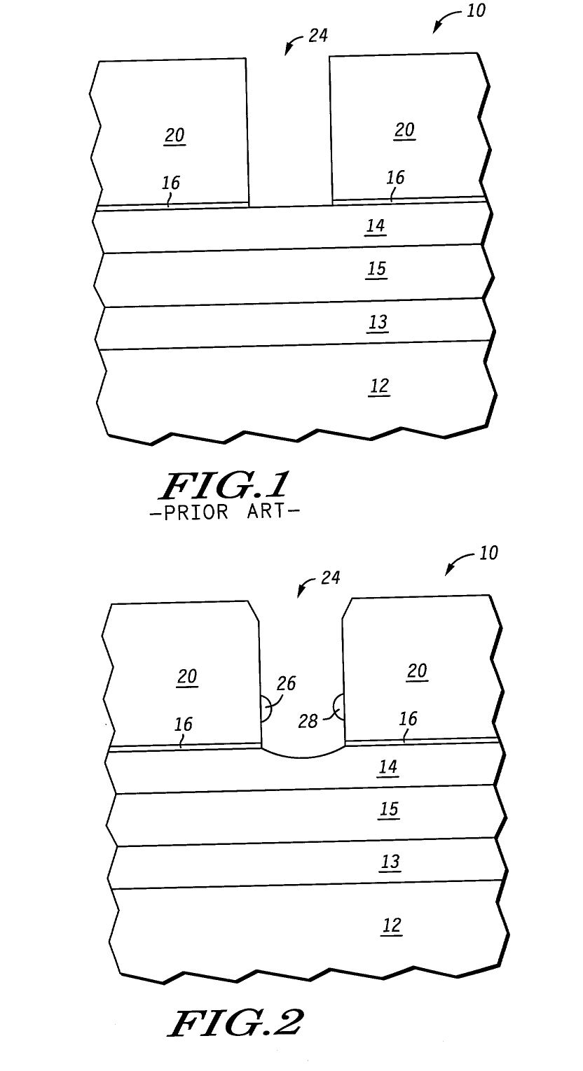

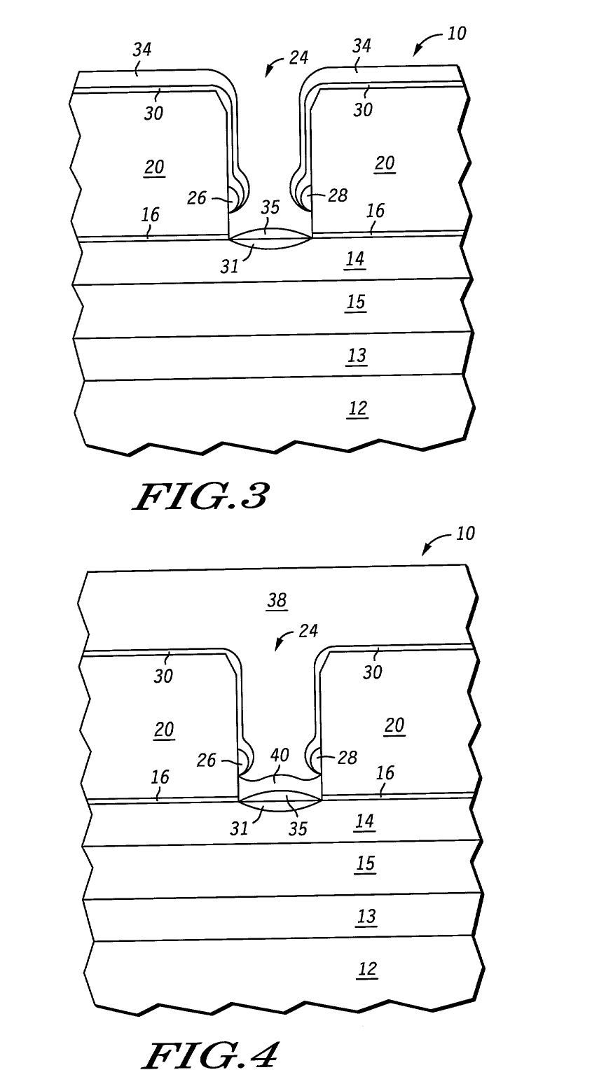

As described above, FIG. 1 illustrates via hole 24 formed within intermetal isolation layer 20 and dielectric layer 16. That is, via hole 24 is a cavity that exposes an underlying metal layer, first metal layer 14. FIG. 2 illustrates via hole 24 after RF (radio frequency) sputtering. During the etch of via hole 24 and the RF sputtering preclean, small amounts of copper from the exposed portions of first metal layer 14 sputter onto the sidewalls of via hole 24. Due to the heat of the wafer during the RF sputtering, the small amounts of sputtered copper on the via hole 24 sidewalls agglomerate to form copper balls 26 and 28. Although FIG. 2 only illustrates two copper balls 26 and 28, any number of copper balls may be formed, where the copper balls may also be of various different sizes. Copper balls may also result within other cavities (such as, for example, trenches) due to the RF sputtering and wafer heating. As will be seen in reference to FIGS. 3 and 4, the copper balls (such as copper balls 26 and 28) result in a roughness inside the cavities (most notably in the vias) which ultimately leads to filling issues and poor electrical results. This problem was previously unknown, and the discovery of these problematic copper balls disclosed herein allowed for an improved fill solution to help remedy the formation of poor electrical contacts, as will be discussed below in reference to various embodiments of the present invention (in reference to FIGS. 5-9).

FIG. 3 illustrates via hole 24 (having copper balls 26 and 28) after the formation (such as, for example, by deposition) of a barrier layer and a seed layer. A barrier layer is formed over intermetal dielectric layer 20 and within via hole 24. However, the barrier layer is not continuous within via hole 24 due to a shadowing effect caused by copper balls 26 and 28. Therefore, as can be seen in FIG. 3, barrier layer portion 30 is formed over intermetal dielectric layer 20 and along portions of the sidewalls within hole 24, and a physically separate barrier layer portion 31 is formed along the bottom of via hole 24. (Barrier layer portions 30 and 31 prevent copper from diffusing into intermetal dielectric layer 20, and may include tantalum, tantalum nitride, titanium, tungsten, titanium nitride, tungsten nitride, or any other appropriate material.) A seed layer is then formed over barrier layer portions 30 and 31. As with the barrier layer, formation (e.g. deposition) of the seed layer results in discontinuous portions due the shadowing effect caused by copper balls 26 and 28. That is, seed layer portion 34 is formed over intermetal dielectric layer 20 and on the vertical sidewalls of via hole 24 and a physically separate seed layer portion 35 is formed on the bottom of via hole 24. (In one embodiment, the seed layer portions 34 and 35 include copper, however, alternate embodiments may use different metals as the seed layer for forming different types of metal fills within via hole 24.) Therefore, copper balls 26 and 28 operate to block the continuous formation of a seed layer.

FIG. 4 illustrates via hole 24 after a filling process. In one embodiment, seed layer portion 34 may be used to electroplate copper to form a copper layer 38 overlying intermetal isolation layer 20 and within via hole 24. However, since the seed layer is discontinuous, portions of the seed layer may not receive the voltage necessary to electroplate the copper. For example, seed layer portion 34 may receive the voltage necessary to electroplate copper to form copper layer 38, but since seed layer portion 35 is discontinuous from and electrically isolated from seed layer portion 34, seed layer portion 34 may not receive any voltage. Therefore, a complete fill of via hole 24 may not be achieved, thus resulting in the formation of void 40 at the bottom of via hole 24. Therefore, it can be seen how the formation of copper balls 26 and 28 result in a roughness along the sidewalls of via hole 24 which prevents a complete fill of via hole 24. Void 40 causes formation of a poor electrical contact having a high resistance which leads to reduced performance of semiconductor device 10. Since this problem was previously unknown, no solution previously existed. Embodiments of the present invention described in reference to FIGS. 5-9, though, present a solution to the problem that was discovered and is illustrated in FIGS. 2-4.

FIG. 5 illustrates via hole 24 after RF sputtering of a pre-cooled wafer, in accordance with an embodiment of the present invention. After formation of via hole 24 (after the via hole etch) but at some point prior to RF sputtering, the wafer containing semiconductor device 10 is cooled such that any sputtered copper 49 onto the sidewalls of via hole 24 remain smooth and do not agglomerate. The additional cooling of the wafer therefore prevents the formation of copper balls within the inlaid structures (such as via hole 24). (Also note that after RF sputtering, some corner rounding of intermetal isolation layer 20 may be achieved.)

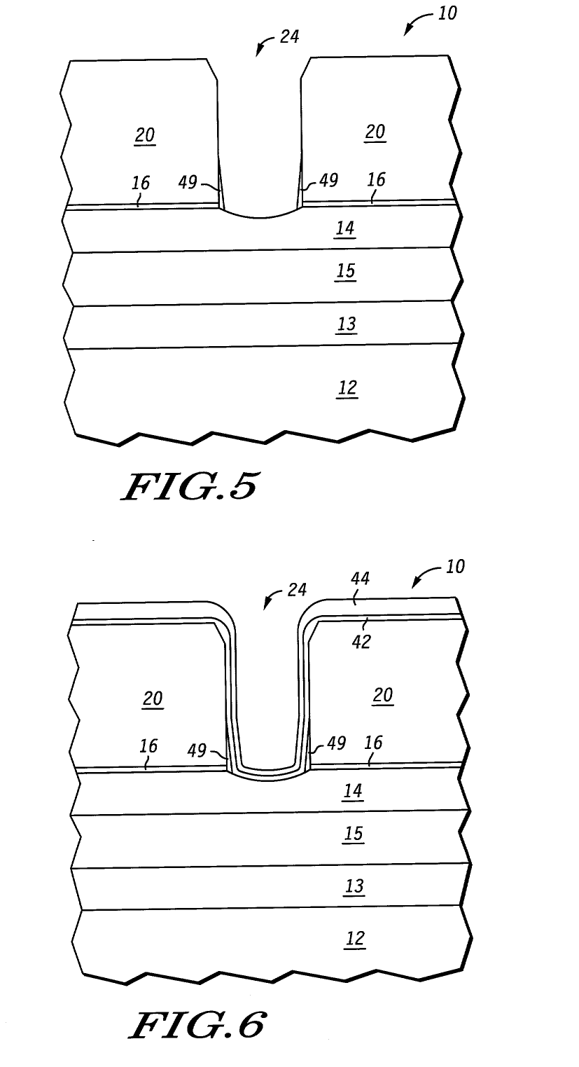

FIG. 6 illustrates via hole 24 after formation of a barrier layer 42 and seed layer 44. Barrier layer 42, similar to barrier layer portion 30 of FIG. 3, is formed over intermetal isolation layer 20 and within via hole 24. However, unlike barrier layer portion 30, barrier layer 42 is continuous within via hole 24 due to the lack of copper balls. (Note that barrier layer 42 may include the same type of materials as listed above for barrier layer portion 30.) Seed layer 44, similar to seed layer portion 34 of FIG. 3, is formed over barrier layer 42 (and within via hole 24). Unlike seed layer portion 34, though, seed layer 44 is also continuous within via hole 24.

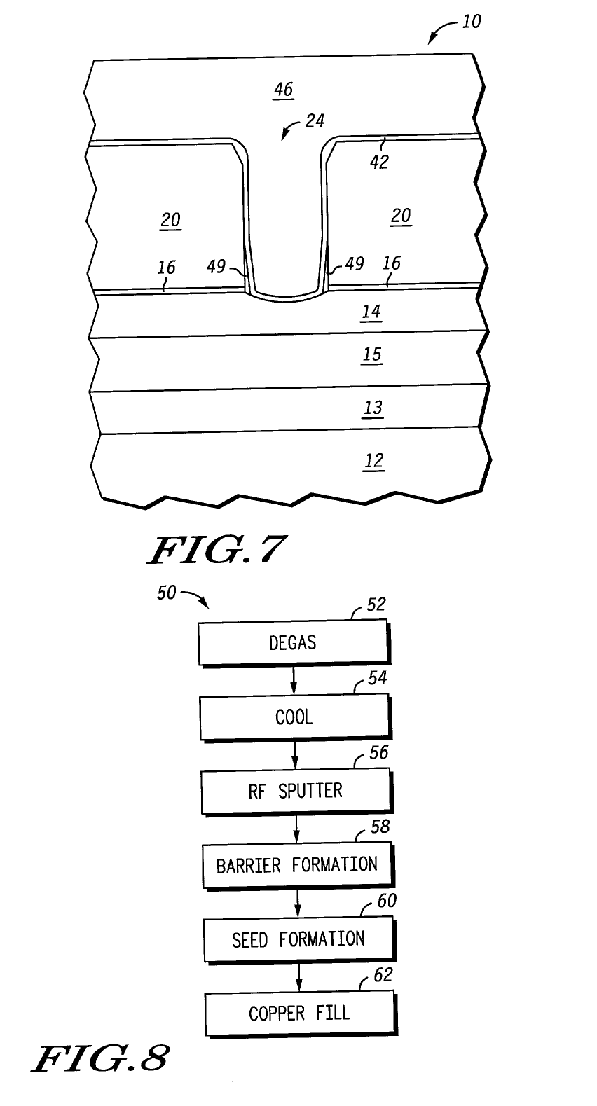

FIG. 7 illustrates via hole 24 after a fill step in accordance with one embodiment of the present invention. Seed layer 44 may be used to electroplate a second metal layer 46 overlying intermetal isolation layer 20 and within via hole 24. (In the embodiment being described herein, seed layer 44 includes copper, and therefore, second metal layer 46 may be referred to as copper layer 46.) Therefore, since seed layer 44 is electrically continuous, a sufficient voltage can be applied to all portions of seed layer 44 within hole 24 thus allowing the second metal layer 46 to be properly electroplated within hole 24 without the formation of voids such as void 40. Due to the lack of copper balls (such as copper balls 26 and 28), an improved copper fill is achieved, thus resulting in an improved electrical contact having low resistivity as compared to the electrical contact formed in FIG. 4. That is, the prevention of void 40 helps to achieve improved electrical contacts.

FIG. 8 illustrates a process flow 50 in accordance with one embodiment of the present invention that may be used to form semiconductor device 10 of FIG. 7 (after formation of copper layer 46). Process 50 begins with a wafer (containing, for example, semiconductor device 10) being provided to a degas stage 52 where the wafer is heated to remove volatile components from the dielectric materials (such as intermetal isolation layer 20 of FIGS. 5-7). In one embodiment, the wafer is heated to a temperature within a range of approximately 100 to 400 degrees Celsius. The wafer may be radiantly or conductively heated. For example, during degas stage 52, the wafer may be heated to a temperature of approximately 250 degrees Celsius. Also, the process pressure used for degas stage 52 may be in a range of approximately le-8 to le-3 Torr. For example, the process pressure may be less than approximately 1 micro Torr.

Process 50 continues with an active cooling stage 54. During cooling stage 54, active cooling is applied to the wafer. That is, it is generally not sufficient to simply allow the wafer to cool with normal ambient exposure due to the slow cooling rate provided by ambient exposure. Therefore, one embodiment of the present invention utilizes a cooling chuck, such as a liquid-cooled chuck, to actively cool the wafer. (An example of a liquid-cooled chuck is provided in FIG. 10.) Intimate wafer contact with the cooling chuck (such as, for example, by mechanical clamping or electrostatic chucking) allows for a greater cooling rate of the wafer as compared to cooling via ambient exposure. In one embodiment, cooling stage 54 cools the wafer to a temperature of less than approximately 200 degrees Celsius. Alternatively, cooling stage 54 may cool the wafer to a temperature of less than approximately 150 or 100 degrees Celsius. Cooling stage 54 should at least occur at some time prior to RF sputter stage 56 such that RF sputter is performed on a sufficiently cooled wafer to prevent the formation of copper balls on the cavity sidewalls. During RF sputter 56, Argon ions are generated to clean cavities (such as, for example, inlaid structures) of the wafer to ensure electrical contacts between metal levels.

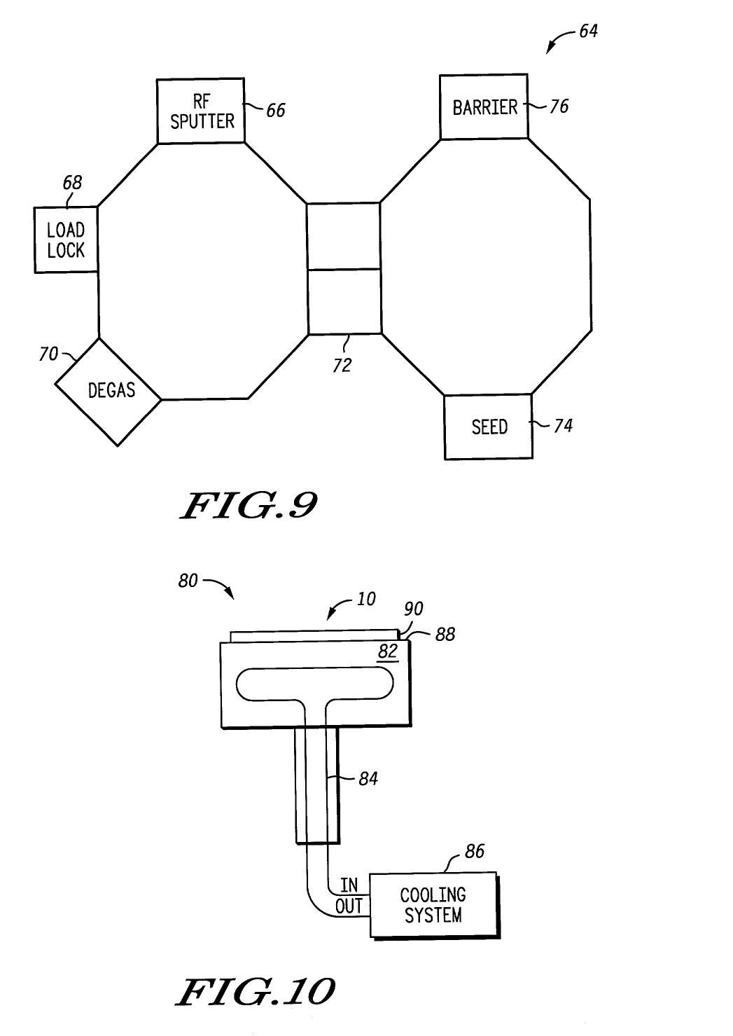

After RF sputter stage 56, process 50 continues with barrier formation stage 58 where a barrier layer is formed overlying the top surface of the wafer and within any cavities (such as, for example, trenches and vias). For example, barrier layer 42 may be formed by blanket deposition in barrier formation stage 58. Process 50 continues with seed formation stage 60 where a seed layer is formed overlying the previously formed barrier layer. For example, seed layer 44 may be formed by blanket deposition in seed formation stage 60. Stages 52, 54, 56, 58, and 60 may all be performed in a metal deposition tool (one example of which will be described in reference to FIG. 9). Other processes may use more or less stages, as needed, and may perform the cooling stage at different times. So long as the wafer is sufficiently cooled prior to RF sputtering, the sputtered copper will be prevented from agglomerating on the sidewalls of wafer cavities, thus resulting in improved low resistance electrical contacts.

FIG. 9 illustrates one embodiment of an enclosed metal deposition tool 64 which may be used to perform stages 52, 54, 56, 58, and 60 of FIG. 8 to form semiconductor device 10 of FIG. 6 (prior to forming copper layer 46). Metal deposition tool 64 includes RF sputter chamber 66, load lock chamber 68, degas chamber 70, pass-through chamber 72, seed chamber 74, and barrier chamber 76. Wafers are generally loaded into load lock chamber 68. From load lock chamber 68, the wafers are generally transferred one at a time between chambers. For example, a wafer from load lock chamber 68 is transferred to degas chamber 70 where degas stage 52 is performed. The wafer is then transferred from degas chamber 70 to RF sputter chamber 66 where RF sputter stage 56 is performed. The wafer is then transferred, via pass-through chamber 72, to barrier chamber 76 where barrier formation stage 58 is performed. The wafer is then transferred to seed chamber 74 where seed formation stage 60 is performed. The wafer is then returned to load lock chamber 68 via pass-through chamber 72.

Cooling stage 54 may be performed in a variety of different ways within metal deposition tool 64. For example, in one embodiment, cooling stage 54 may be performed in situ within degas chamber 70. That is, degas chamber 70 may utilize a liquid-cooled chuck for wafer cooling. In this example, the active cooling may be performed within degas chamber 70 after degas stage 52 is performed. Alternatively, cooling stage 54 may be performed in situ within RF sputter chamber 66 prior to performing RF sputter stage 56. That is, RF sputter chamber 66 may utilize a liquid-cooled chuck where cooling by the liquid-cooled chuck can even continue during RF sputtering. In another embodiment, cooling stage 54 may be performed in both degas chamber 70 and RF sputter chamber 66. That is, both chambers 70 and 66 may utilize a liquid-cooled chuck where the wafer is partially cooled in degas chamber 70 after degas stage 52 and partially cooled in RF sputter chamber 66 prior to RF sputter stage 56. In yet another embodiment, metal deposition tool 64 may include a separate active cooling chamber (not shown) where each wafer may be transferred to the active cooling chamber after exiting degas chamber 70 and prior to entering RF chamber 66. Alternatively, cooling stage 54 may be performed using a separate cooling chamber in addition to being cooled in situ within degas chamber 70 or RF sputter chamber 66 or both.

Therefore, active cooling stage 54 may be implemented in a variety of different ways, and is not limited to the embodiments described in reference to FIG. 9. That is, alternate embodiments may use different tools having different chambers than those illustrated in FIG. 9. For example, in an alternate embodiment, RF sputter chamber 66 may be referred to as a cleaning chamber where a cleaning stage is performed. In one embodiment, this cleaning stage may include the RF sputtering of a noble gas.

Shown in FIG. 10 is a liquid-cooled chuck 80 that may be used in metal deposition tool 64 of FIG. 9 comprising a body 82, a liquid carrying line 84, a cooling system 86, and a top surface 88. In FIG. 10 is shown a wafer 90 that has thereon semiconductor device structure 10. Wafer 90 may be affirmatively held to chuck 80 electrostatically or via a mechanical clamp. Chuck 80 is useful for actively cooling device substrate 12 and all of device structure 10 by conduction. Therefore, chuck 80 may be used within degas chamber 70, RF sputter chamber 66, or both, or within a separate cooling chamber. This is a conventional cooling chuck known in the art.

In the foregoing specification, the invention has been described with reference to specific embodiments. However, one of ordinary skill in the art appreciates that various modifications and changes can be made without departing from the scope of the present invention as set forth in the claims below. For example, any of the materials discussed herein are also provided as examples. For example, first metal layer 14 may be another metal instead of copper, such as, for example, palladium. In this example, copper balls 26 and 28 and copper layer 46 would also be of the other metal (e.g. palladium) rather than copper. That is, embodiments of the present invention are not intended to be limited to copper. Also, alternate embodiments may not require a barrier layer or seed layer. In these embodiments, barrier layer 42 may be optional or seed layer 44 may be optional or both may be optional. For example, copper layer 46 may be plated from the barrier layer. Also, alternate embodiments may form copper layer 46 using different formation processes. For example, electroless plating may be used instead of electroplating. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A method for forming an inlaid structure in a semiconductor device, comprising:
providing a semiconductor substrate;
providing a first metal layer over the semiconductor substrate;
forming a dielectric layer over the first metal layer;
forming a cavity in the dielectric layer through to the first metal layer to provide an exposed portion of the first metal layer and an exposed portion of the dielectric layer;
degassing the exposed portion of the dielectric layer;
cooling the substrate after degassing the exposed portion of the dielectric layer;
sputter cleaning the exposed portion of the first metal layer after cooling the substrate;
forming a seed layer in the cavity; and
filling the cavity with a second metal layer by electroplating to form the inlaid structure.

2. The method of claim 1, wherein the first and second metal layers are copper.

3. The method of claim 1, wherein the step of cooling comprises:
providing a liquid-cooled chuck; and
placing the substrate on the liquid-cooled chuck.

4. The method of claim 1, further comprising continuing cooling the substrate during the step of sputtering.

5. The method of claim 4, further comprising placing the substrate in an enclosed, low pressure, metal deposition tool, and wherein the steps of degassing, sputtering, cooling, continuing cooling, forming the seed layer, and filling the cavity are performed in the metal deposition tool.

6. The method of claim 5, wherein metal deposition tool has a sputter chamber, wherein the steps of cooling, continuing cooling, and sputtering are performed in the sputter chamber.

7. The method of claim 6, wherein the step of degassing comprises heating the substrate.

8. The method of claim 7, further comprising depositing a barrier layer in the cavity before the step of forming a seed layer in the cavity.

9. The method of claim 8, wherein the barrier layer comprises at least one of tantalum, titanium, and tungsten.

10. The method of claim 9, further comprising at least one of tantalum nitride, titanium nitride, and tungsten nitride.

11. The method of claim 10, wherein the first metal layer, the second metal layer, and the seed layer comprise copper.

12. A method for forming an inlaid structure in a semiconductor device, comprising:
providing a semiconductor substrate;
providing a first metal layer over the semiconductor substrate;
forming a dielectric layer over the first metal layer;
forming a cavity in the dielectric layer through to the first metal layer to provide an exposed portion of the first metal layer and an exposed portion of the dielectric layer;
degassing the exposed portion of the dielectric layer;
cooling the substrate after degassing the exposed portion of the dielectric layer;
cleaning the exposed portion of the first metal layer after degassing the exposed portion of the dielectric layer; and
filling the cavity with a second metal layer to form the inlaid structure.

13. The method of claim 12, further comprising:
providing a metal deposition tool being under low pressure and having a degas chamber and a cleaning chamber, and wherein
the step of degassing is performed in the degas chamber; and
the step of cleaning is performed in the cleaning chamber.

14. The method of claim 13, wherein the step of cooling is performed in the cleaning chamber.

15. The method of claim 13, wherein the step of cooling is performed in the degas chamber.

16. The method of claim 13, wherein the metal deposition tool further comprises a cooling chamber and the step of cooling is performed in the cooling chamber.

17. The method of claim 12, wherein the step of cleaning comprises rf sputtering with a noble gas.

18. The method of claim 12, further comprising depositing a seed layer comprising copper in the cavity, and wherein the first metal layer and the second metal layer comprise copper.

19. The method of claim 18, wherein the step of filling the cavity is by electroplating.

20. A method for forming an inlaid structure in a semiconductor device, comprising:
providing a semiconductor substrate;
forming an active layer over the substrate;
providing first dielectric layer over the active layer;
providing a first metal layer over the first dielectric layer;
forming a second dielectric layer over the first metal layer comprising copper;
forming a cavity in the second dielectric layer through to the first metal layer to provide an exposed portion of the first metal layer and an exposed portion of the second dielectric layer;
heating the exposed portion of the dielectric layer at a pressure less than approximately one micro Torr;
applying active cooling to the substrate after heating the exposed portion of the second dielectric layer to a temperature less than one hundred degrees Celsius;
sputter cleaning the exposed portion of the second metal layer after cooling the substrate;
forming a seed layer comprising copper in the cavity; and
filling the cavity with a second metal layer comprising copper by electroplating to form the inlaid structure.
